(19) United States
(12) Patent Application Publication
(10) Pub. No.: US 2026/0239623 A1
(43) Pub. Date: Aug. 13, 2026

(54) SEMICONDUCTOR DEVICE HAVING A TRANSISTOR AND A MANUFACTURING METHOD OF THE SEMICONDUCTOR DEVICE

(71) Applicant: SK hynix Inc., Icheon-si Gyeonggi-do (KR)

(72) Inventor: Jung Goo PARK, Icheon-si Gyeonggi-do (KR)

(73) Assignee: SK hynix Inc., Icheon-si Gyeonggi-do (KR)

(21) Appl. No.: 19/272,568

(22) Filed: Jul. 17, 2025

(30) Foreign Application Priority Data
Feb. 13, 2025 (KR) 10-2025-0018799

(51) Int. Cl. H10B 43/40

(52) U.S. Cl. CPC H10B 43/40

(57) ABSTRACT

A semiconductor device, and a method of manufacturing the same, includes a semiconductor substrate having an active region including a first impurity injection region, a second impurity injection region, and a channel region between the first impurity injection region and the second impurity injection region. Each of the first impurity injection region and the second impurity injection region includes a nitrogen region adjacent to a upper surface of the semiconductor substrate and a source/drain region separated from the upper surface of the semiconductive substrate by the nitrogen region and including conductive impurities.

### CROSS-REFERENCE TO RELATED APPLICATION

The present application claims priority under 35 U.S.C. § 119(a) to Korean patent application number 10-2025-0018799 filed on February 13, 2025, in the Korean Intellectual Property Office, the entire contents of which application is incorporated herein by reference.

### BACKGROUND

### 1. Technical Field

Various embodiments of the present disclosure generally relate to a semiconductor device and a manufacturing method of the semiconductor device, and more particularly, to a semiconductor device having a transistor and a method of manufacturing the same.

### 2. Related Art

Semiconductor devices are applied to various electronic systems such as small electronic devices, automobiles, medical care devices, and data centers, and the devices are highly integrated and high-capacity according to user needs. The semiconductor devices include transistors. The electrical characteristics of the transistors may be degraded for a variety of reasons during manufacturing of the semiconductor devices.

### SUMMARY

According to an embodiment of the present disclosure, a semiconductor device may include: a semiconductor substrate including an active region, the active region including a first impurity injection region, a second impurity injection region, and a channel region between the first impurity injection region and the second impurity injection region; a gate insulating layer and a gate electrode stacked over the channel region; and a multiple insulating structure covering surfaces of the first impurity injection region, the second impurity injection region, the gate insulating layer, and the gate electrode. Each of the first impurity injection region and the second impurity injection region may include a nitrogen region adjacent to an upper surface of the semiconductor substrate and a source/drain region spaced apart from the upper surface of the semiconductor substrate by the nitrogen region, the source/drain region including conductive impurities.

According to an embodiment of the present disclosure, a method of manufacturing a semiconductor device may include: forming a stack structure including a gate insulating layer and a gate electrode over an active region of a semiconductor substrate; forming a nitrogen region in each of a first region and a second region of the active region disposed on opposite sides of the gate electrode; forming a buffer layer to cover the nitrogen region of each of the first region and the second region, a sidewall of the stack structure, and an upper surface of the stack structure; and forming a source/drain region by injecting conductive impurities into a portion of each of the first region and the second region, the portion separated from the upper surface of the semiconductor substrate by the nitrogen region.

### BRIEF DESCRIPTION OF THE DRAWINGS

FIG. 1 is a block diagram illustrating an electronic system including a semiconductor device according to an embodiment of the present disclosure;

FIG. 2 is a block diagram illustrating a semiconductor device according to an embodiment of the present disclosure;

FIG. 3 is an isometric diagram illustrating a memory cell array structure and a peripheral circuit structure of a semiconductor device according to an embodiment of the present disclosure;

FIGS. 4A and 4B are cross-sectional views illustrating a transistor of a semiconductor device according to an embodiment of the present disclosure;

FIGS. 5A and 5B are cross-sectional views illustrating a semiconductor device including a transistor according to some embodiments of the present disclosure; and

FIG. 6A, FIG. 6B, FIG. 6C, FIG. 6D, FIG. 6E, and FIG. 6F are cross-sectional views illustrating various configurations formed by utilizing a method of manufacturing a transistor according to some embodiments of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “over,” “lower,” “upper,” and other terms implying relative spatial relationship or orientation are utilized only for the purpose of ease of description or reference to a drawing and are not otherwise limiting. It will be understood that when an element or layer is referred to as being "on," "connected to," or "coupled to" another element or layer, it can be directly on, connected, or coupled to the other element or layer or intervening elements or layers may be present. In contrast, when an element is referred to as being "directly on," "directly connected to," or "directly coupled to" another element or layer, there are no intervening elements or layers present. The cross-hatching throughout the figures illustrates corresponding or similar areas between the figures rather than indicating the materials associated with the areas.

Some embodiments of the present disclosure may be directed to a semiconductor device which may improve electrical characteristics of a transistor included in the semiconductor device and a method of manufacturing the same.

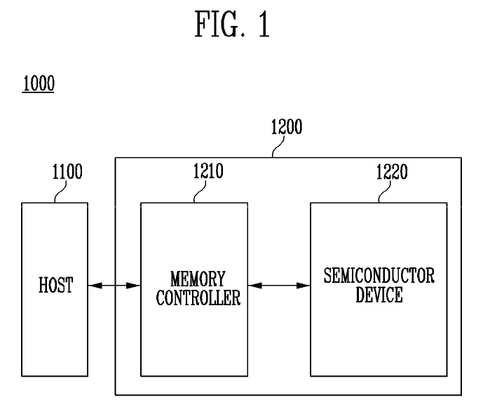

FIG. 1 is a block diagram illustrating an electronic system 1000 including a semiconductor device according to an embodiment of the present teachings.

Referring to FIG. 1, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200 based on an interface. The interface may include one or more of a Double Data Rate (DDR) interface, a Universal Serial Bus (USB) interface, a Multimedia Card (MC) interface, an embedded MMC (eMMC) interface, a Peripheral Component Interconnection (PCI) interface, a PCI-express (PCI-E) interface, an Advanced Technology Attachment (ATA) interface, a Serial-ATA interface, a Parallel-ATA interface, a Small Computer System Interface (SCSI), an Enhanced Small Disk Interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor device 1220. In an embodiment, the storage device 1200 may be a storage medium such as a Solid-State Drive (SSD), Universal Serial Bus (USB) memory, or the like.

The memory controller 1210 may store data in the semiconductor device 1220 under the control of the host 1100 or read data stored in the semiconductor device 1220.

The semiconductor device 1220 may include a single memory chip or a plurality of memory chips. The semiconductor device 1220 may store data or output stored data under the control of the memory controller 1210.

The semiconductor device 1220 may be a non-volatile memory device. The semiconductor device 1220 may include a memory cell array and a peripheral circuit to control operation of the memory cell array. The memory cell array may include a plurality of memory cells. Each memory cell may be a non-volatile memory cell. In an embodiment, each memory cell may be configured as a NAND flash memory cell, a ferroelectric memory cell, a variable resistance memory cell, or the like.

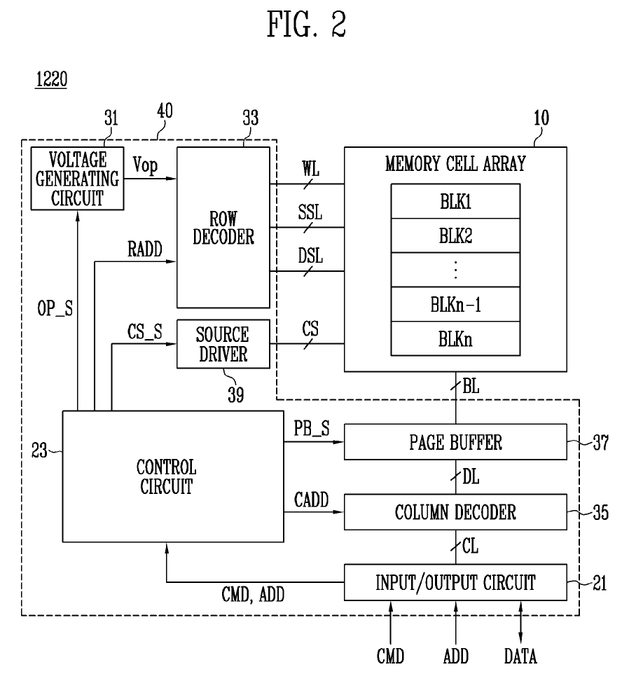

FIG. 2 is a block diagram illustrating the semiconductor device 1220 according to an embodiment of the present disclosure.

Referring to FIG. 2, the semiconductor device 1220 may include a peripheral circuit 40 and a memory cell array 10. In an embodiment, the semiconductor device 1220 may include the peripheral circuit 40 of a NAND flash memory device and the memory cell array 10. Hereinafter, embodiments of the present disclosure will be described based on the peripheral circuit 40 of the NAND flash memory device and the memory cell array 10, but embodiments of the present disclosure are not limited thereto.

The peripheral circuit 40 is configured to perform a program operation for storing data in the memory cell array 10, a read operation for outputting data stored in the memory cell array 10, and an erase operation for erasing data stored in the storage cell array 10. In an embodiment, the peripheral circuit 40 may include an input/output circuit 21, a control circuit 23, a voltage generating circuit 31, a row decoder 33, a column decoder 35, a page buffer 37, and a source driver 39.

The peripheral circuit 40 may be connected to the memory cell array 10 through a plurality of common source structures CS, a plurality of bit lines BL, a plurality of drain select lines DSL, a plurality of word lines WL, and a plurality of source select lines SSL.

The input/output circuit 21 may transmit a command CMD and an address ADD received from an external device (for example, the memory controller 1210 illustrated in FIG. 1) of the semiconductor device 1220 to the control circuit 23. The input/output circuit 21 may exchange data DATA with an external device and the column decoder 35.

The control circuit 23 may output an operation signal OP_S, a row address RADD, a common source control signal CS_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transmit the operating voltages Vop to the plurality of drain select lines DSL, the plurality of word lines WL, and the plurality of source select lines SSL in response to the row address RADD.

The column decoder 35 may transmit the data DATA input from the input/output circuit 21 to the page buffer 37 in response to the column address CADD, or transmit the data DATA stored in the page buffer 37 to the input/output circuit 21. The column decoder 35 may exchange the data DATA with the input/output circuit 21 through the column line CL. The column decoder 35 may exchange the data DATA with the page buffer 37 via the data line DL.

The page buffer 37 may control the bit lines BL in response to the page buffer control signal PB_S. In the program operation, the page buffer 37 may store the data DATA received from the column decoder 35 in response to the page buffer control signal PB_S, and may apply voltages to the plurality of bit lines BL based on the stored data DATA. In the read operation, the page buffer 37 may sense voltages or currents of the bit lines BL in response to the page buffer control signal PB_S and may store the sensed result.

The source driver 39 may control a voltage or a bias applied to each of the plurality of common source structures CS in response to the common source control signal CS_S received from the control circuit 23, or may ground each of the plurality the common source structures CS.

The memory cell array 10 includes a plurality of memory blocks BLK1 to BLKn, where n is a natural number greater than or equal to 2. The plurality of memory blocks BLK1 to BLKn are connected to the page buffer 37 through the plurality of bit lines BL. The erase operation may be controlled in units of the common source structure CS or units of memory blocks. At least one source layer may be connected to the common source structure CS.

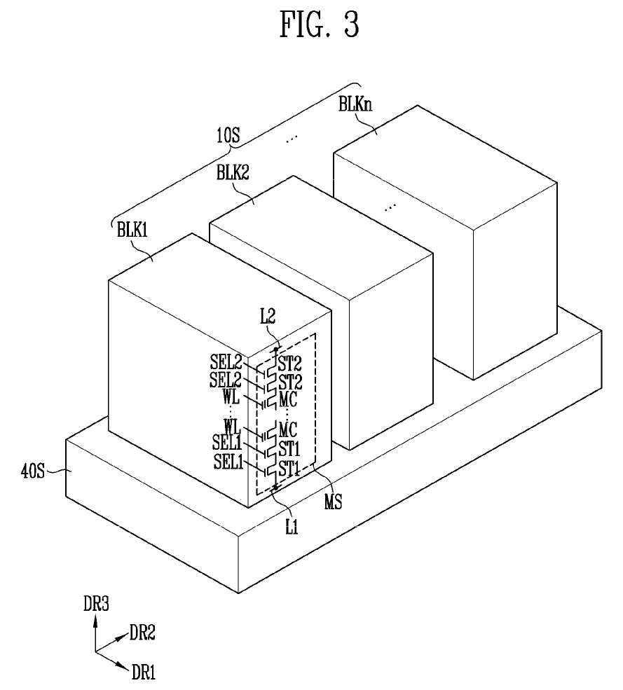

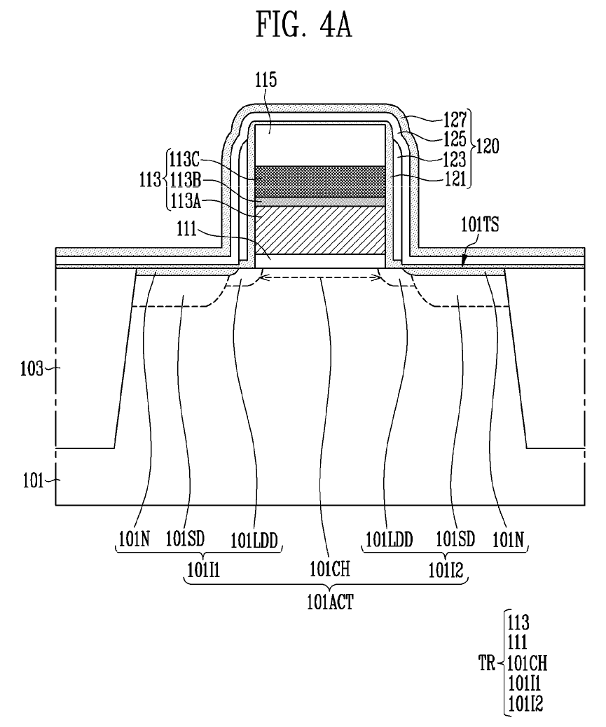

FIG. 3 is an isometric diagram illustrating a memory cell array structure 10S and a peripheral circuit structure 40S of the semiconductor device 1220 according to an embodiment of the present disclosure.

A first direction DR1, a second direction DR2, and a third direction DR3 shown in FIG. 3 are directions in which axes intersecting with each other face, and in an embodiment, the first direction DR1, the second direction DR2 and the third direction DR3 may correspond to directions in which an X-axis, a Y-axis, and a Z-axis face, respectively.

Referring to FIG. 3, the memory cell array structure 10S includes the plurality of memory blocks BLK1 to BLKn, where n is a natural number greater than or equal to 2. In an embodiment, each of the plurality of memory blocks BLK1 to BLKn in the NAND flash memory device may include a plurality of memory cell strings MS. The plurality of memory cell strings MS may be arranged in a plurality of rows and a plurality of columns. The memory cell strings MS arranged in a line in the first direction DR1 form each row, and the memory cell strings MS arrayed in a line in the second direction DR2 form each column.

Each of the memory cell strings MS may be connected to a first conductive layer L1, a second conductive layer L2, at least one first select line SEL1, the plurality of word lines WL, and at least one second select line SEL2. One of the first conductive layer L1 and the second conductive layer L2 forms a source layer and the other forms a bit line. The first conductive layer L1 and the second conductive layer L2 may be spaced apart from each other in the third direction DR3, and may be electrically connected to both ends of the memory cell string MS. One of the first select line SEL1 and the second select line SEL2 is used as a source select line, and the other is used as a drain select line. The at least one first select line SEL1, the plurality of word lines WL, and the at least one second select line SEL2 may be disposed between the first conductive layer L1 and the second conductive layer L2, and they may be disposed to be spaced apart from each other in the third direction DR3. The at least one first select line SEL1 is disposed between the first conductive layer L1 and the plurality of word lines WL. In an embodiment, two first select lines SEL1 may be disposed between the first conductive layer L1 and the plurality of word lines WL. The at least one second select line SEL2 is disposed between the second conductive layer L2 and the plurality of word lines WL. In an embodiment, two second select lines SEL2 may be disposed between the second conductive layer L2 and the plurality of word lines WL. The memory cell string MS includes a first select transistor ST1 connected to the first select line SEL1, a plurality of memory cells MC connected to the plurality of word lines WL, and a second select transistor ST2 connected to the second select line SEL2. One of the first select transistor ST1 and the second select transistor ST2 is used as a source select transistor, and the other is used as a drain select transistor. The first select transistor ST1, the plurality of memory cells MC, and the second select transistor ST2 may be connected in series through a channel pillar electrically connected to the first conductive layer L1 and the second conductive layer L2.

The peripheral circuit structure 40S includes a plurality of transistors forming the peripheral circuit 40 described with reference to FIG. 2. Each of the plurality of transistors may include a gate insulating layer having a thickness designed to match a driving voltage for driving each transistor. In an embodiment, the plurality of transistors may include a first transistor to which a first voltage is applied as a maximum gate voltage, a second transistor to which a second voltage is applied as a maximum gate voltage, and a third transistor to which a third voltage is applied as a maximum gate voltage. The first transistor includes a first gate insulating layer of a first thickness, the second transistor includes a second gate insulating layer of a second thickness, and the third transistor includes a third gate insulating layer of a third thickness. The first voltage is greater than the second voltage, and the second voltage is greater than the third voltage. In this case, the first thickness is greater than the second thickness, and the second thickness is greater than the third thickness, so that the breakdown voltage characteristics of the first to third transistors may be ensured.

The memory cell array structure 10S and the peripheral circuit structure 40S overlap with each other in the third direction DR3. After forming the memory cell array structure 10S and the peripheral circuit structure 40S, a hydrogen annealing process for removing defects may be performed. Each of the plurality of transistors in the peripheral circuit structure 40S may include a nitrogen region capable of reducing or blocking a movement path of hydrogen ions generated in the hydrogen annealing process or the like.

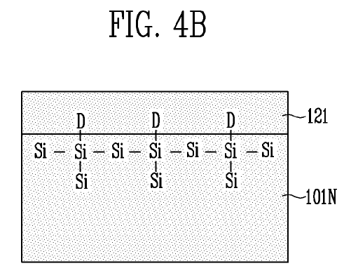

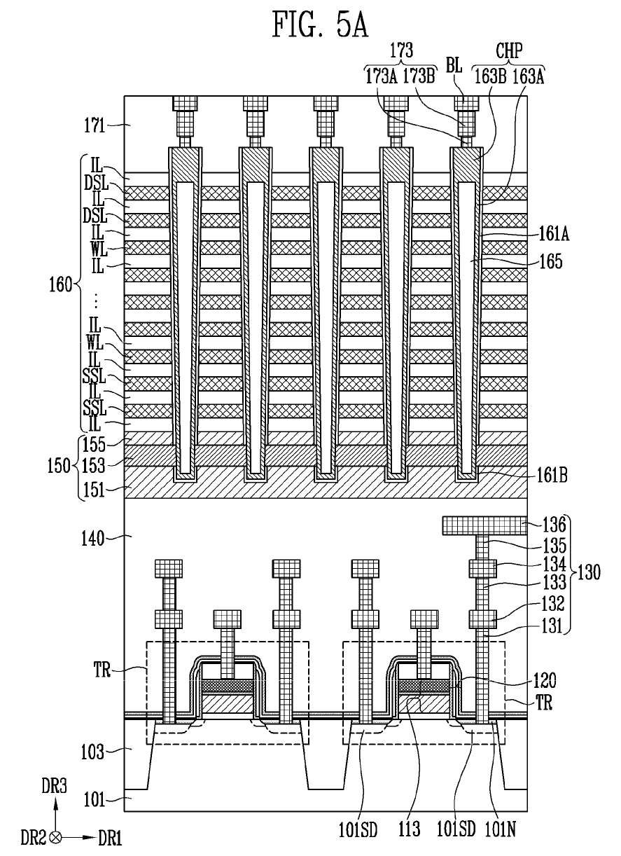

FIGS. 4A and 4B are cross-sectional views illustrating a transistor TR of a semiconductor device according to an embodiment of the present disclosure.

Referring to FIG. 4A, the transistor TR may include a channel region 101CH, a first impurity injection region 101I1, and a second impurity injection region 101I2 formed in a semiconductor substrate 101, and may include a gate insulating layer 111 and a gate electrode 113 stacked over the channel region 101CH of the semiconductor substrate 101.

The semiconductor substrate 101 includes a semiconductor material. In an embodiment, the semiconductor material may include one or more of a group IV semiconductor, a group III-V compound semiconductor, and a group II-VI compound semiconductor. The group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The semiconductor substrate 101 may further include a dielectric layer. In an embodiment, the semiconductor substrate 101 may be a Silicon-On-Insulator (SOI) substrate or a Germanium-On-Insulator (GeOI) substrate. The semiconductor substrate 101 may further include an organic material. In an embodiment, the semiconductor substrate 101 may include graphene.

The semiconductor substrate 101 may be a bulk wafer or an epitaxial layer grown by a Selective Epitaxial Growth (SEG) method. Alternatively, the semiconductor substrate 101 may be a layer formed by a Metal Induced Lateral Crystallization (MILC) method, and may partially include a metal.

The semiconductor substrate 101 may have a single crystal, a polycrystalline, or an amorphous state. The semiconductor substrate 101 may include impurities of Group II, III, IV, V, or VI elements. In an embodiment, the semiconductor substrate 101 may include an n-well region doped with n-type impurities, a p-well region doped with p-type impurities, or an n-well area and a p-well area.

The semiconductor substrate 101 includes an active region 101ACT partitioned by an isolation layer 103. The channel region 101CH, the first impurity injection region 101I1, and the second impurity injection region 101I2 of the transistor TR are formed in the active region 101ACT.

The channel region 101CH is formed between the first impurity injection region 101I1 and the second impurity injection region 101I2. The channel region 101CH may include conductive impurities such as n-type impurities and p-type impurities designed in consideration of a threshold voltage of the transistor TR.

Each of the first impurity injection region 101I1 and the second impurity injection region 101I2 includes a nitrogen region 101N and a source/drain region 101SD. The nitrogen region 101N is disposed adjacent to an upper surface 101TS of the semiconductor substrate 101. The nitrogen region 101N may include a dose of nitrogen ions from 1E13 ions/cm² to 1E14 ions/cm², written in exponential notation. The nitrogen region 101N may be formed to have a thickness of 120 angstroms (Å) to 140 Å from the upper surface 101TS of the semiconductor substrate 101 to the inside of the semiconductor substrate 102. A majority carrier of the source/drain region 101SD may include n-type impurities or p-type impurities depending on the electrical characteristics of the transistor TR. In an embodiment, the transistor TR is a P-channel Metal Oxide Semiconductor (PMOS) transistor, and the source/drain region 101SD includes p-type impurities as the majority carrier. In another embodiment, the transistor TR is an N-channel Metal Oxide Semiconductor (NMOS) transistor, and the source/drain region 101SD includes n-type impurities as the majority carrier. The source/drain region 101SD is spaced apart from the upper surface 101TS of the semiconductor substrate 101 by the nitrogen region 101N. According to an embodiment of the present disclosure, the diffusion of hydrogen ions around the source/drain region 101SD may be blocked or reduced by the nitrogen region 101N. According to an embodiment of the present disclosure, the diffusion of hydrogen ions around the source/drain region 101SD may be blocked or reduced by combining the nitrogen ions inside the nitrogen region 101N with the diffused hydrogen ions.

Each of the first impurity injection region 101I1 and the second impurity injection region 101I2 may further include a doped region 101LDD. The doped region 101LDD includes impurities of the same conductivity type as the source/drain region 101SD as the majority carrier. The doped region 101LDD is disposed between the source/drain region 101SD and the channel region 101CH, and the concentration of impurities of the conductivity type of the majority carrier is included at a lower concentration in the doped region 101LDD than in the source/drain region 101SD. Leakage current between the source/drain regions 101SD of the first impurity injection region 101I1 and the second impurity injection region 101I2 may be reduced by the doped region 101LDD including relatively low concentration of conductivity type impurities.

The gate insulating layer 111 is disposed between the gate electrode 113 and the channel region 101CH of the semiconductor substrate 101, and it may include a single layer or a multilayer structure of various insulating materials such as a silicon oxide layer, a silicon nitride layer, and a silicon oxynitride layer. In an embodiment, the gate insulating layer 111 may be formed as a double layer structure including a silicon oxide layer and a silicon nitride layer.

The gate electrode 113 may include a single-layer or multi-layer structure of various conductive materials such as a doped semiconductor material, a conductive metal nitride, a metal, and a metal-semiconductor compound. In an embodiment, the gate electrode 113 may include a doped silicon 113A, a stack 113B including titanium, tungsten nitride, and tungsten silicon nitride, and a tungsten 113C.

The gate electrode 113 may be disposed between a gate capping pattern 115 and the gate insulating layer 111. The gate capping pattern 115 may include a single-layer or multi-layer structure of various insulating materials such as a silicon oxide layer, a silicon nitride layer, and a silicon oxynitride layer. In an embodiment, the gate capping pattern 115 may include a tetraethylothosilicate (TEOS) oxide layer.

The surface of the transistor TR may be covered with a multiple insulating structure 120. The multiple insulating structure 120 may cover surfaces of the first impurity injection region 101I1, the second impurity injection region 101I2, the gate insulating layer 111, the gate electrode 113, and the gate capping pattern 115, and may extend to cover the isolation layer 103.

The multiple insulating structure 120 may include a buffer layer 125 and a diffusion barrier layer 127. Each of the buffer layer 125 and the diffusion barrier layer 127 may extend to cover an upper surface of the first impurity injection region 101I1, an upper surface of the second impurity injection region 101I2, a sidewall of the gate electrode 113, and an upper surface of the gate electrode 113. The diffusion barrier layer 127 may reduce further diffusion of dopants or diffusion of hydrogen ions into the transistor TR. The diffusion barrier layer 127 may include silicon nitride. The buffer layer 125 may be disposed between each of the first impurity injection region 101I1 and the second impurity injection region 101I2 and the diffusion barrier layer 127 to reduce stress applied to the semiconductor substrate 101 during formation of the diffusion barrier layer 127. The buffer layer 125 may include silicon oxide and may extend between each of the gate electrode 113 and the gate capping pattern 115 and the diffusion barrier layer 127. During forming the oxide layer for the buffer layer 125, because the nitrogen region 101N may reduce or prevent the semiconductor substrate 101 from being oxidized, the density of trap sites due to the oxidation of the semiconductor substrate 101 may be reduced.

The multiple insulating structure 120 may further include a spacer oxide layer 123 and a capping nitride layer 121. The spacer oxide layer 123 is disposed between the buffer layer 125 and the sidewall of the gate electrode 113. The capping nitride layer 121 is disposed between each of the first impurity injection region 101I1 and the second impurity injection region 101I2 on one side and the buffer layer 125 on the other side. The capping nitride layer 121 extends between the gate electrode 113 and the spacer oxide layer 123. The capping nitride layer 121 has a thinner thickness between each of the first impurity injection region 101I1 and the second impurity injection region 101I2 and the buffer layer 125 than between the gate electrode 113 and the spacer oxide layer 123. The capping nitride layer 121 may extend between the buffer layer 125 and the gate capping pattern 115.

FIG. 4B is an enlarged view of the nitrogen region 101N of the semiconductor substrate 101 shown in FIG. 4A and the capping nitride layer 121 over the nitrogen region 101N.

Referring to FIGS. 4A and 4B, a silicon-deuterium bonding (Si-D) may be formed along a surface of the nitrogen region 101N. A trap site at the upper surface 101TS of the semiconductor substrate 101 may be reduced by the silicon-deuterium bonding (Si-D).

The transistor TR described with reference to FIGS. 4A and 4B may be applied to various semiconductor devices, and in an embodiment, may be applied to a transistor forming a peripheral circuit of a NAND flash memory device.

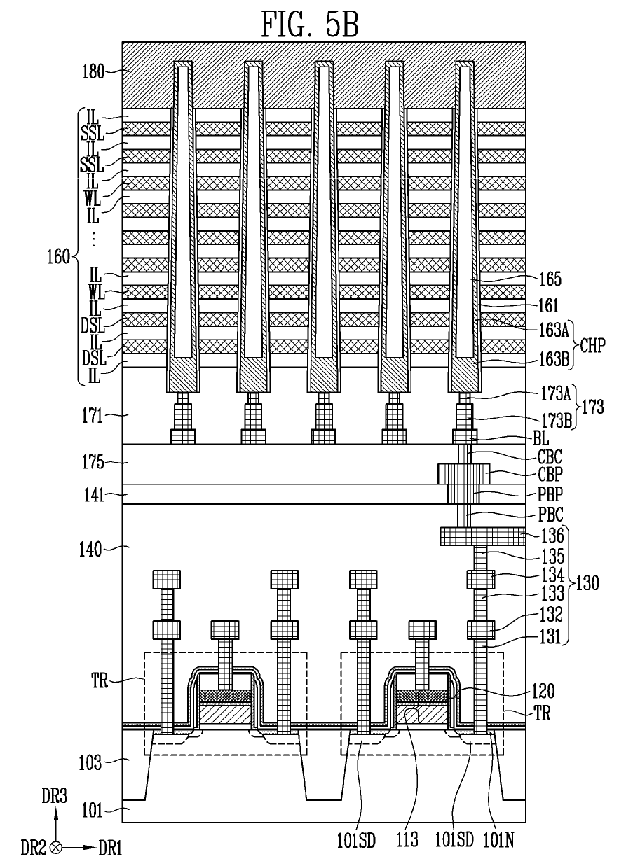

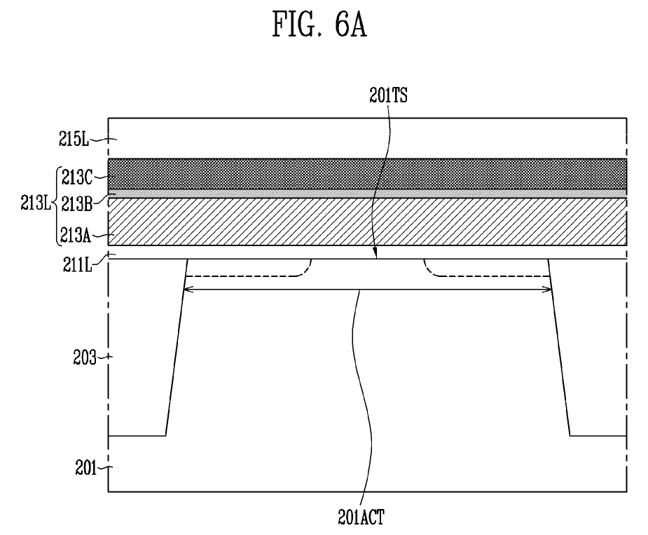

FIGS. 5A and 5B are cross-sectional views illustrating a semiconductor device including a transistor according to some embodiments of the present disclosure. In an embodiment, FIGS. 5A and 5B are cross-sectional views illustrating the semiconductor device described with reference to FIG. 3.

Referring to FIGS. 5A and 5B, a peripheral circuit structure of a semiconductor device may include the semiconductor substrate 101 having the isolation layer 103 formed therein, the transistor TR described with reference to FIG. 4A, the multiple insulating structure 120 described with reference to FIGS. 4A, a peripheral circuit-side insulating structure 140 formed over the semiconductor substrate 101 to cover the multiple insulating structure 120, and interconnections 130 connected to the transistor TR. The peripheral circuit-side insulating structure 140 may include multilayer insulating layers. Each of the interconnections 130 may include conductive patterns 131, 132, 133, 134, 135, and 136 disposed in the peripheral circuit-side insulation structure 140. The interconnections 130 may be connected to the gate electrode 113 and the source/drain region 101SD of the transistor TR. The lowest layer conductive pattern 131 of the interconnection 130 connected to the source/drain region 101SD may penetrate the nitrogen region 101N.

The memory cell array structure of the semiconductor device may include a doped semiconductor structure 150 or 180, a gate stack structure 160, the bit line BL, a channel pillar CHP, and a memory layer 161A or 161. The gate stack structure 160 is disposed between the doped semiconductor structure 150 or 180 and the bit line BL, and the channel pillar CHP passes through the gate stack structure 160 and is connected to the doped semiconductor structure 150 or 180.

The gate stack structure 160 may include a plurality of conductive layers SSL, WL, and DSL formed in a flat plate shape extending in the first direction DR1 and the second direction DR2, and a plurality of interlayer insulating layers IL. The plurality of conductive layers SSL, WL, and DSL and the plurality of interlayer insulating layers IL may be alternately disposed one by one in the third direction DR3.

The plurality of conductive layers SSL, WL, and DSL include at least one source select line SSL, at least one drain select line DSL, and the plurality of word lines WL disposed between the source select line SSL and the drain select line DSL. The source select line SSL is connected to a gate electrode of the source select transistor, the drain select line DSL is connected to a gate electrode of the drain select transistor, and the plurality of word lines WL are connected to a plurality of gates of the plurality of memory cells, respectively. Each of the plurality of conductive layers SSL, WL, and DSL may include various conductive materials such as a doped semiconductor layer and a metal layer. The doped semiconductor layer may include a doped silicon layer. The metal layer may include tungsten, copper, molybdenum, or the like. Each of the plurality of conductive layers SSL, WL, and DSL may further include a metal barrier layer. The metal barrier layer may include a metal nitride layer, and the metal nitride layer may include titanium nitride, tantalum nitride, molybdenum nitride, or the like. In an embodiment, the metal barrier layer may include a double layer of titanium and titanium nitride. Each of the plurality of interlayer insulating layers IL may include an insulating material such as a silicon oxide layer or a silicon oxynitride layer.

The channel pillar CHP extends in the third direction DR3 to penetrate through the gate stack structure 160. The channel pillar CHP includes a channel layer 163A. The channel layer 163A may include a semiconductor material, such as silicon (Si), germanium (Ge), or a mixture thereof, that may be used as a channel region of a string of memory cells. The channel layer 163A may have a tubular shape. The channel pillar CHP including the channel layer 163A having the tubular may further include a core insulating layer 165 and a capping pattern 163B disposed in a tubular central region formed of the channel layer 163A. The capping pattern 163B may include a semiconductor layer doped with conductive impurities. The conductive impurities may include n-type impurities or may include n-type impurities and p-type impurities. In an embodiment, the capping pattern 163B may include n-type doped silicon that includes n-type impurities as a majority carrier.

The memory layer 161A or 161 may surround a sidewall of the channel pillar CHP. The memory layer 161A or 161 may include a tunnel insulating layer, a data storage layer, and a blocking insulating layer. Although not shown in the drawing, the tunnel insulating layer is disposed between the channel pillar CHP and the gate stack structure 160, the data storage layer is disposed between the tunnel layer and the gate stack structure 160, and the blocking insulating layer is disposed between the data storage layer and the gate stack structure 160. The tunnel insulating layer may include an oxide such as silicon dioxide (SiO₂). The data storage layer may include a material layer capable of storing data that is changed by using Fowler-Nordheim tunneling. In an embodiment, the data storage layer may include a charge trap layer or may include an insulating layer including conductive nanodots. The charge trap layer may include a silicon nitride layer. The blocking insulating layer may include an oxide such as silicon dioxide (SiO₂), a high-dielectric insulator having a higher dielectric constant than silicon dioxide, or the like. The high-dielectric insulating material may include an aluminum oxide layer, a hafnium oxide layer, or the like.

The source select transistor may be formed at an intersection of the source select line SSL and the channel layer 163A, the drain select transistor may be formed at an intersection of the drain select line DSL and the channel layer 163A, and a plurality of memory cells may be formed at an intersection of the plurality of word lines WL and the channel layer 163A. The source select transistor, the plurality of memory cells, and the drain select transistor may be connected in series through the channel layer 163A of the channel pillar CHP to form the memory cell string MS illustrated in FIG. 3.

The channel pillar CHP may be connected to the doped semiconductor structure 150 or 180 and the bit line BL.

The doped semiconductor structure 150 or 180 may include at least one doped semiconductor layer. The doped semiconductor layer of the doped semiconductor structure 150 or 180 may include n-type impurities or p-type impurities. In an embodiment, a doped semiconductor structure 150 or 180 may include at least one of a first conductive doped semiconductor layer including n-type impurities as a majority carrier and a second conductive doped semiconductor layer including p-type impurities as a majority carrier. The first conductive doped semiconductor layer may serve as a source layer, and the second conductive doped semiconductor layer may serve as a well region. The source layer of the doped semiconductor structure 150 or 180 may be in direct contact with the sidewall or a bottom surface of the channel pillar CHP.

Referring to FIG. 5A, in an embodiment, a portion of a sidewall of the channel layer 163A may form a contact surface with the doped semiconductor structure 150. In an embodiment, the doped semiconductor structure 150 may include a first source layer 151, a second source layer 155, and a contact source layer 153 between the first source layer 151 and the second source layer 155. Each of the first source layer 151, the second source layer 155, and the contact source layer 153 may include a doped semiconductor layer. The channel layer 163A may extend into each of the first source layer 151, the second source layer 155, and the contact source layer 153. The memory layer 161A may extend between the second source layer 155 and the channel layer 163A. A dummy memory layer 161B may be disposed between the first source layer 151 and the channel layer 163A. The dummy memory layer 161B may include the same materials as the memory layer 161A. The contact source layer 153 may be disposed between the memory layer 161A and the dummy memory layer 161B, and it may be in contact with the channel layer 163A.

Referring to FIG. 5B, an end of the channel layer 163A may extend into the doped semiconductor structure 180 and may form a contact surface with the doped semiconductor structure 180.

Referring to FIGS. 5A and 5B, the capping pattern 163B of the channel pillar CHP may be electrically connected to the bit line BL via a bit line connection structure 173. The bit line connection structure 173 and the bit line BL may be disposed in the insulating structure 171. The insulating structure 171 may include multiple insulating layers covering the gate stack structure 160. The bit line connection structure 173 may include one or more conductive patterns. In an embodiment, the bit line connection structure 173 may include a first conductive pattern 173A and a second conductive pattern 173B overlapped with each other in the third direction DR3.

One of the doped semiconductor structure 150 or 180 and the bit line BL may be disposed adjacent to the peripheral circuit-side insulating structure 140. Referring to FIG. 5A, in an embodiment, the doped semiconductor structure 150 may be disposed closer to the peripheral circuit-side insulating structure 140 than the bit line BL. Referring to FIG. 5B, in an embodiment, the bit line BL may be disposed closer to the peripheral circuit-side insulating structure 140 than the doped semiconductor structure 180.

Referring to FIGS. 5A and 5B, the memory cell array structure including the doped semiconductor structure 150 or 180 or the like may be formed on the peripheral circuit-side insulating structure 140 or may be connected to the peripheral circuit structure by a bonding process.

Referring to FIG. 5A, in an embodiment, a process for forming a memory cell array structure such as a doped semiconductor structure 150 may be performed over the peripheral circuit-side insulating structure 140.

Referring to FIG. 5B, in an embodiment, the peripheral circuit structure may further include a peripheral circuit-side interposing insulating layer 141 over the peripheral circuit-side insulating structure 140, a peripheral circuit-side bonding pad PBP inside the peripheral circuit-side interposed insulating layer 141, and a peripheral circuit-side bonding contact PBC extending from the peripheral circuit-side bonding pad PBP to be connected to the uppermost layer conductive pattern 136 of the interconnection 130. In an embodiment, the memory cell array structure may further include a cell-side interposed insulating layer 175 covering the insulating structure 171, a cell-side bonding pad CBP inside the cell-side interposed insulating layer 175, and a cell-side bonding contact CBC extending from the cell-side bonding pad CBP to be connected to a wiring such as the bit line BL. The gate stack structure 160, the memory layer 161, the channel pillar CHP, the bit line connection structure 173, the bit line BL, the insulating structure 171, the cell-side interposed insulating layer 175, the cell-side bonding contact CBC, and the cell-side bonding pad CBP of the memory cell array structure may be formed over a sacrificial substrate separately from the peripheral circuit structure. Thereafter, the cell-side bonding pad CBP is bonded to the peripheral circuit-side bonding pad PBP, and after removing the sacrificial substrate, the end of the channel layer 163A facing the direction opposite to the direction toward the bit line BL, the DR3 direction, may be exposed. After exposing the end of the channel layer 163A, the doped semiconductor structure 180 may be formed, and the doped semiconductor structure 180 may be in contact with the exposed end of the channel layer 163A.

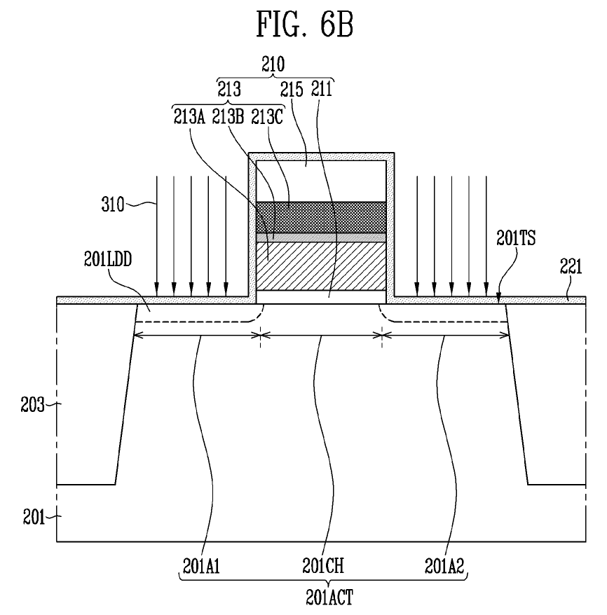

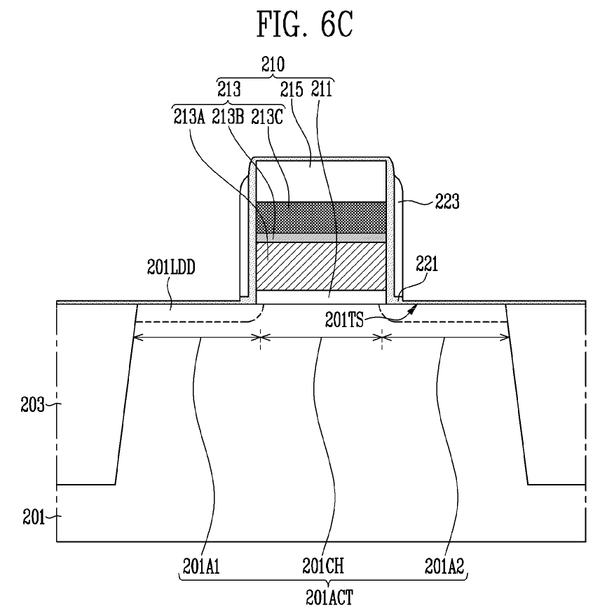

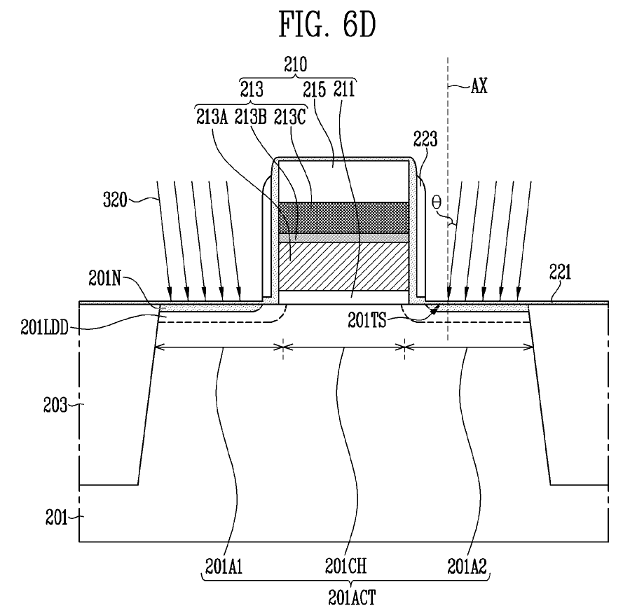

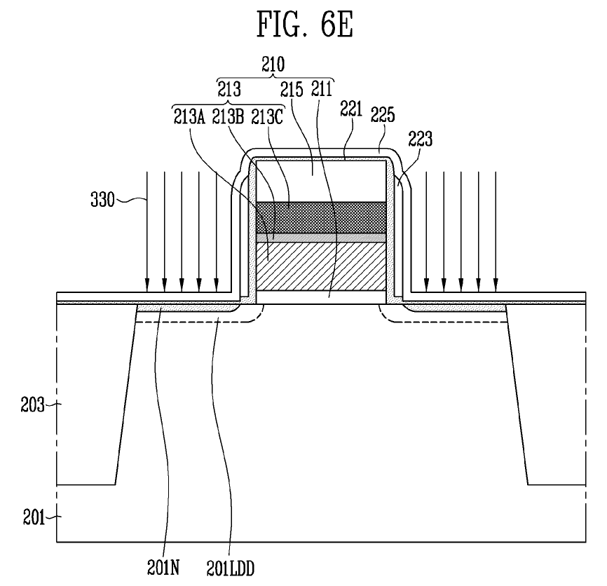

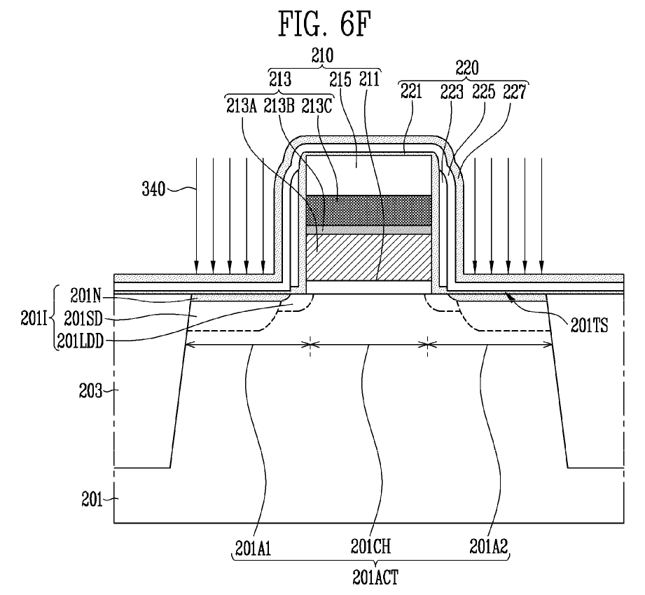

FIGS. 6A, 6B, 6C, 6D, 6E and 6F, are cross-sectional views illustrating various configurations formed by utilizing a method of manufacturing a transistor according to some embodiments of the present disclosure.

Referring to FIG. 6A, an isolation layer 203 is formed in a semiconductor substrate 201. An active region 201ACT of the semiconductor substrate 201 is partitioned by the isolation layer 203.

The semiconductor substrate 201 may include various semiconductor materials, such as the semiconductor materials of the semiconductor substrate 101 described with reference to FIG. 4A.

In an embodiment, forming the isolation layer 203 may include forming a trench in the semiconductor substrate 201 and filling the trench with an insulator.

Subsequently, a gate insulating layer 211L, a gate electrode layer 213L, and a gate capping layer 215L may be stacked over an upper surface 201TS of the semiconductor substrate 201. The gate insulating layer 211L may be formed by various methods such as vapor deposition and oxidation. The gate electrode layer 213L may include various conductive materials. In an embodiment, the gate electrode layer 213L may include doped silicon 213A; a stack 213B including titanium, tungsten nitride, and tungsten silicon nitride; and a tungsten 213C. The gate capping layer 215L may include various insulating materials.

Referring to FIG. 6B, the gate capping layer 215L and the gate electrode layer 213L shown in FIG. 6A are etched using a photolithography process and an etching process. As a result, a gate capping pattern 215 and a gate electrode 213 are formed. In an embodiment, portions of the gate insulating layer 211L shown in FIG. 6A may be removed so that a first region 201A1 and a second region 201A2 of the active region 201ACT are exposed on opposite sides of the gate electrode 213. An embodiment of the present disclosure is not limited thereto, and the portions of the gate insulating layer 211L shown in FIG. 6A over the first region 201A1 and the second region 201A2 may cover the first region 202A1 and the first region 203A2 with a thickness reduced by the etching process. Hereinafter, the etched gate insulating layer is referred to using the reference number “211.”

Through the above-described processes, after a stack structure 210 including the gate insulating layer 211, the gate electrode 213, and the gate capping pattern 215 is formed, a capping nitride layer 221 may be formed. The capping nitride layer 221 extends along surfaces of the first region 201A1 and the second region 201A2 of the semiconductor substrate 101 and a surface of the stack structure 210.

Subsequently, conductive impurities 310 including n-type impurities or p-type impurities at a first concentration may be injected into the first region 201A1 and the second region 201A2 of the semiconductor substrate 101 covered with the capping nitride layer 221. The conductive impurities 310 may be injected from the upper surface 201TS of the semiconductor substrate 201 at a first depth. An annealing process may then be performed to activate the injected conductive impurities. Subsequently, a doped region 201LDD is formed in each of the first region 201A1 and the second region 201A2 of the semiconductor substrate 101, and a channel region 201CH having a doping profile different from that of the doped region 201LDD is formed between the first region 201A1 and the third region 201A2.

The capping nitride layer 221 may protect the semiconductor substrate 201 during the impurity injecting process to form the doped region 201LDD.

Referring to FIG. 6C, a spacer oxide layer 223 may be formed on a sidewall of the capping nitride layer 221 so that an end of the doped region 201LDD adjacent to the gate electrode 213 is covered with the spacer oxide layer 223.

In an embodiment, forming the spacer oxide layer 223 may include forming an oxide layer over a surface of the capping nitride layer 221 and etching the oxide layer by an etching process such as etching back using a difference in etching selectivity between the oxide layer and the nitride layer. Etching the oxide layer may be performed such that portions of the capping nitride layer 221 over the first region 201A1 and the second region 201A2 of the semiconductor substrate 101 and another portion of the capping nitride layer 211 over an upper surface of the stack structure 210 are exposed. During etching of the oxide layer, the thickness of the exposed region of the capping nitride layer 221 may be reduced.

Referring to FIG. 6D, nitrogen ions 320 are injected into each of the first region 201A1 and the second region 201A2 of the semiconductor substrate 101, thereby forming a nitrogen region 201N. In an embodiment, the nitrogen region 201N may be formed by injecting the nitrogen ions 320 at an injection angle θ of 1° to 5° with respect to an axis AX orthogonal to the upper surface 201TS of the semiconductor substrate 201 at an energy of 5 KeV to 10 KeV.

The nitrogen region 201N may be formed thinner than the doped region 201LDD in the doped region 201LDD. In an embodiment, the nitrogen region 201N may be distributed to have a thickness of 120 Å to 140 Å from the upper surface 201TS of the semiconductor substrate 201 toward the inside of the semiconductor substrate. The nitrogen region 201N may be spaced apart from the channel region 201CH by the doped region 201LDD.

Referring to FIG. 6E, a buffer layer 225 is formed over the spacer oxide layer 223 and the capping nitride layer 221. The buffer layer 225 may cover the nitrogen region 201N of each of the first region 201A1 and the second region 201A2 shown in FIG. 6D with the capping nitride layer 221 interposed between the buffer layer 225 and the nitrogen region 201N. The buffer layer 225 may cover a sidewall of the stack structure 210 with the spacer oxide layer 223 and the capping nitride layer 221 interposed between the buffer layer 225 and the stack structure 210. The buffer layer 225 may cover the upper surface of the stack structure 210, with the capping nitride layer 221 interposed between the buffer layer 225 and the stack structure 210.

The buffer layer 225 may include a High Temperature Oxide (HTO) layer formed at a high temperature of 800 degrees Celsius (°C) or higher. In an embodiment, the buffer layer 225 may include silicon oxide. The oxidation of the semiconductor substrate 201 during the formation of the buffer layer 225 may be reduced or prevented by the nitrogen region 201N.

Subsequently, deuterium ions 330 may be supplied to a surface of the nitrogen region 201N by a deuterium annealing process. The deuterium ions 330 may combine with a trap site on the surface of the semiconductor substrate 201 to reduce surface defects of the semiconductor substrate 201. The deuterium annealing process may be carried out at a temperature of 750 °C to 850 °C and a pressure of 15 atmospheres (atm) to 20 atm for 30 minutes to 90 minutes. After performing the deuterium annealing process, one or both of a nitrogen annealing process and an oxygen annealing process may be further performed in an in-situ manner.

Referring to FIG. 6F, a diffusion barrier layer 227 is formed over the buffer layer 225. The diffusion barrier layer 227 may cover the nitrogen region 201N of each of the first region 201A1 and the second region 201A2 with the buffer layer 225 interposed between the diffusion barrier layer 227 and the nitrogen region 201N. The diffusion barrier layer 227 may improve the diffusion of unnecessary dopants and hydrogen ions into the semiconductor substrate 201. The diffusion barrier layer 227 may include silicon nitride. The capping nitride layer 221, the spacer oxide layer 223, the buffer layer 225, and the diffusion barrier layer 227 may form a multiple insulating structure 220.

Subsequently, conductive impurities 340 including n-type impurities or p-type impurities at a second concentration may be injected into the first region 201A1 and the second region 201A2 of the semiconductor substrate 101. The conductive impurities 340 may be injected from the upper surface 201TS of the semiconductor substrate 201 at a second depth. The annealing process may then be performed to activate the injected conductive impurities. Subsequently, a source/drain region 201SD may be formed in each of the first region 201A1 and the second region 201A2 of the semiconductor substrate 101.

The conductive impurities 340 are of the same conductivity type as the conductive impurities forming the majority carrier of the doped region 201LDD, and may be n-type impurities or p-type impurities. The second concentration may be greater than the first concentration described above with reference to FIG. 6B, and the second depth may be controlled to be deeper than the first depth described above with reference to FIG. 6B.

The source/drain region 201SD is formed in each of the first region 201A1 and the second region 201A2 of the semiconductor substrate 201, and it is formed at a position spaced apart from the upper surface 201TS of the semiconductor substrate 211 by the nitrogen region 201N. A portion of the doped region 201LDD which maintains the conductive impurities at the lower concentration than the source/drain region 201SD may be disposed between the source/drain region 201SD and the channel region 201CH.

The source/drain region 201SD, the doped region 201LDD, and the nitrogen region 201N described above may form an impurity injection region 201I.

In an embodiment, after forming the multiple insulating structure 220 and the impurity injection region 201I, a subsequent process for forming the interconnection 130, the doped semiconductor structure 150, the gate stack structure 160, the channel pillar CHP, the bit line BL, and the like illustrated in FIG. 5A, and the hydrogen annealing process may be performed. In another embodiment, after forming the multiple insulating structure 220 and the impurity injection region 201I, a subsequent process of forming the interconnection 130, the peripheral circuit-side bonding contact PBC, the peripheral circuit-side bonding pad PBP, and the like illustrated in FIG. 5B, a subsequent process of bonding the cell-side bonding pad CBP to the peripheral circuit-side bonding pad PBP illustrated in FIG. 5B, and the hydrogen annealing process may be performed.

Hydrogen ions generated during the hydrogen annealing process may be blocked by the nitrogen region 201N or combined with nitrogen ions in the nitrogen region 201N. The transistor formed to have the nitrogen region 201N may be provided by performing the nitrogen ion injecting process as in the embodiment of the present disclosure and may reduce diffusion of hydrogen ions to the interface between the gate insulating layer 211 and the semiconductor substrate 201 compared to the transistor formed without the nitrogen ion injecting process. Accordingly, according to an embodiment of the present disclosure, the trap site density at the interface between the gate insulating layer 211 and the semiconductor substrate 201 may be improved.

In addition to the deuterium annealing process described with reference to FIG. 6E, one or both of the nitrogen annealing process and the oxygen annealing process may be additionally performed to improve leakage current in the off-state of the transistor.

According to some embodiments of the present disclosure, a source/drain region of a transistor is separated from an upper surface of a semiconductor substrate by a nitrogen region formed inside the semiconductor substrate. Because the nitrogen region may reduce the oxidation of the semiconductor substrate, the density of trap sites due to the oxidation of the semiconductor substrate may be reduced around the source/drain region. In addition, because the nitrogen region may reduce or prevent the diffusion of hydrogen ions into the transistor, the electrical characteristics of the transistor may be improved.

What is claimed is:

1. A semiconductor device, comprising:
a semiconductor substrate including an active region, the active region including a first impurity injection region, a second impurity injection region, and a channel region between the first impurity injection region and the second impurity injection region;
a gate insulating layer and a gate electrode stacked over the channel region; and
a multiple insulating structure covering surfaces of the first impurity injection region, the second impurity injection region, the gate insulating layer, and the gate electrode,
wherein each of the first impurity injection region and the second impurity injection region includes:
a nitrogen region adjacent to an upper surface of the semiconductor substrate; and
a source/drain region spaced apart from the upper surface of the semiconductor substrate by the nitrogen region, the source/drain region including conductive impurities.

2. The semiconductor device of claim 1, further comprising a silicon-deuterium bond formed along a surface of the nitrogen region.

3. The semiconductor device of claim 1, wherein each of the first impurity injection region and the second impurity injection region further includes a doped region including the conductive impurities at a lower concentration than in the source/drain region, the doped region disposed between the source/drain region and the channel region.

4. The semiconductor device of claim 1, wherein the multiple insulating structure includes:
a diffusion barrier layer covering an upper surface of the first impurity injection region, an upper surface of the second impurity injection region, a sidewall of the gate electrode, and an upper surface of the gate electrode; and
a buffer layer disposed between the diffusion barrier layer and each of the first impurity injection region and the second impurity injection region, the buffer layer extending between the gate electrode and the diffusion barrier layer.

5. The semiconductor device of claim 4, wherein the buffer layer includes silicon oxide, and the diffusion barrier layer includes silicon nitride.

6. The semiconductor device of claim 4, wherein the multiple insulating structure further includes:
a spacer oxide layer disposed between the buffer layer and the sidewall of the gate electrode; and
a capping nitride layer disposed between the first impurity injection region and the buffer layer and between the second impurity injection region and the buffer layer, the capping nitride layer extending between the gate electrode and the spacer oxide layer.

7. The semiconductor device of claim 1, further comprising a peripheral circuit-side insulating structure formed over the semiconductor substrate to cover the multiple insulating structure;
interconnections connected to the gate electrode and the source/drain region, respectively, the interconnections embedded in the peripheral circuit-side insulating structure; and
a memory cell array structure disposed over the peripheral circuit-side insulating structure.
